(19) United States
(12) Patent Application Publication
(10) Pub. No.: US 2014/0043036 A1
(43) Pub. Date: Feb. 13, 2014

(54) DETECTION CIRCUIT AND DETECTION METHOD

(71) Applicants: Yizhuang Zhuang, Shenzhen (CN); Mingfeng Deng, Shenzhen (CN); Jungmao Tsai, Shenzhen (CN); Shiueshih Liao, Shenzhen (CN); Songxian Wen, Shenzhen (CN)

(72) Inventors: Yizhuang Zhuang, Shenzhen (CN); Mingfeng Deng, Shenzhen (CN); Jungmao Tsai, Shenzhen (CN); Shiueshih Liao, Shenzhen (CN); Songxian Wen, Shenzhen (CN)

(21) Appl. No.: 13/582,423

(22) PCT Filed: Aug. 16, 2012
(86) PCT No.: PCT/CN12/80213

§ 371 Date: Sep. 2, 2012

(30) Foreign Application Priority Data
Aug. 13, 2012 (CN) 201210286432.4

(51) Int. Cl. G01R 31/28

(52) U.S. Cl. 324/537

(57) ABSTRACT

The present disclosure provides a detection circuit and a detection method. The detection circuit used for detecting an electrostatic discharge (ESD) protective device that is inversely soldered, the ESD protective device includes a first diode, a second diode, and a third diode; the cathodes of the first diode, the second diode and the third diode are mutually connected, and an anode of the third diode is coupled to a ground terminal of the circuit by a divider resistor. The detection circuit includes a comparator. The comparator is configured with a first input end connected to the reference voltage and a second input end coupled to the anode of the third diode, and an output end of the comparator is coupled to a warning device.

### TECHNICAL FIELD

The present disclosure relates to the field of electronic technique, and more particularly to a detection circuit and a detection method.

### BACKGROUND

The so-called electrostatic discharge (ESD) refers to the intensive discharge phenomenon generated when an energized conductive object (such as human body) is in contact or dose to another conductive object (such as electronic equipment) so that the electronic equipment is damaged or malfunctioned because of ESD. To prevent such phenomenon, it is required that overvoltages generated during the discharge are not applied to the circuit of the electronic equipment, and an ESD protective device is used for this purpose.

The ESD protective device is configured between a signal line of the circuit and around. As shown in FIG. 1, the ESD protective device employs a structure which separates a pair of discharge electrodes into a symmetrical structure, thereby having high resistance under normal operating condition so that signal(s) may not flow to ground. However, because the discharge electrodes are in a symmetrical structure, inverse soldering is easy to occur when the ESD protective device is soldered on a printed circuit board (PCB). It is difficult to visually find which component has been inverted because the typical circuit board has a high integration level and small component volume. FIG. 2 is a circuit diagram of the ESD protective device which is inverted. At this moment, Vcc pin(s) is grounded. When signal(s) 1 or signal(s) 2 is input, a part of signal passes through a1 or b1 and is attenuated by Vcc grounding, resulting in an incomplete signal output. At present, component inversion may not be detected.

### SUMMARY

In view of the above-described problems, the aim of the present disclosure is to provide a detection circuit and a detection method capable of automatically detecting an electrostatic discharge (ESD) protective device that is inversely soldered.

The aim of the present disclosure is achieved by the following technical scheme.

A detection circuit used for detecting the ESD protective device that is inversely soldered, the ESD protective device comprises a first diode, a second diode, and a third diode. The cathodes of the first diode, the second diode and the third diode are mutually connected, and an anode of the third diode is coupled to a ground terminal of the circuit by a divider resistor. The detection circuit comprises a comparator. The comparator is configured with a first input end connected to a reference voltage, and a second input end coupled to the anode of the third diode. The comparator comprises an output end. The output end of the comparator is coupled to a warning device.

Furthermore, the warning device is a voice operated device. An anode of the voice operated device is coupled to the output end of the comparator, and a cathode of the voice operated device is grounded. This is a technical scheme of the voice warning device. When the comparator outputs high electrical level, the voice operated device makes a sound. When the comparator outputs low electrical level, the voice operated device keeps silent.

Furthermore, the warning device comprises an indicator light. An anode of the indicator light is coupled to the output end of the comparator, and a cathode of the indicator light is grounded. This is a technical scheme of the photoelectric warning device. When the comparator outputs high electrical level, the indicator light turns on. When the comparator outputs low electrical level, the indicator light turns off.

Furthermore, the comparator comprises an operation amplifier. A positive input end of the operation amplifier is coupled to a non-ground terminal of the divider resistor, and a negative input end of the operation amplifier is connected to a reference voltage. This is a specific comparator circuit. When the ESD device is in a inverse soldering state, the operation amplifier outputs high electrical level. On the contrary, the operation amplifier outputs low electrical level.

Furthermore, the comparator comprises an operation amplifier. A positive input end of the operation amplifier is connected to a reference voltage, and a negative input end of the operation amplifier is coupled to a non-ground terminal of the divider resistor. This is a specific comparator circuit. When the ESD device is in a inverse soldering state, the operation amplifier outputs low electrical level. On the contrary, the operation amplifier outputs high level.

A method used for detecting the IESD protective device that is inversely soldered comprises the following steps:

A: coupling the output end of the comparator of the detection circuit to the warning device; and

B: connecting the first input end of the comparator of the detection circuit to the reference voltage, and connecting the second input end of the comparator of the detection circuit to the anode of the third diode of the ESD protective device. Wherein, the aforementioned steps can be performed regardless of sequence.

Furthermore, in the step A, the warning device is a yoke operated device. An anode of the voice operated device is coupled to the output end of the comparator, and a cathode of the voice operated device is grounded. This is a technical scheme of the voice warning device. When the comparator outputs high electrical level, the voice operated device makes a sound. When the comparator outputs low electrical level, the voice operated device keeps silent.

Furthermore, in the step A, the warning device comprises an indicator light. An anode of the indicator light is coupled to the output end of the comparator, and a cathode of the indicator light is grounded. This is a technical scheme of the photoelectric warning device. When the comparator outputs high electrical level, the indicator light turns on. When the comparator outputs low electrical level, the indicator light turns off.

Furthermore, in the step B, the comparator of the detection circuit comprises an operation amplifier. A positive input end of the operation amplifier is coupled to a non-ground terminal of the divider resistor, and a negative input end of the Operation amplifier is connected to a reference voltage. This is a specific comparator circuit. When the ESD device is in a inverse soldering state, the operation amplifier outputs high level. On the contrary, the operation amplifier outputs low electrical level.

Furthermore, in the step B, the comparator of the detection circuit comprises an operation amplifier. A positive input end of the operation amplifier is connected to a reference voltage, and a negative input end of the operation amplifier is coupled to a non-ground terminal of the divider resistor. This is a specific comparator circuit. When the ESD device is in a inverse soldering state, the operation amplifier outputs low electrical level. On the contrary, the operation amplifier outputs high electrical level.

In the present disclosure, because one input end of the comparator is coupled to the anode of the third diode of the ESD protective device, and is grounded by the resistor which is in series connection with the third diode, when the ESD protective device is normally soldering or inverse soldering, an voltage difference at the two ends of the resistor are different. Thus, the comparator can detect the voltage change, and output signal(s) to drive the warning device to take corresponding action, thereby automatically detecting the ESD protective device that is inversely soldered.

### BRIEF DESCRIPTION OF FIGURES

FIG. 1 is a schematic diagram of a typical ESD protective device in a normal soldering state.

FIG. 2 is a schematic diagram of a typical ESD protective device in a inverse soldering state.

FIG. 3 is a schematic diagram of a detection system of an ESD protective device employing a voice operated device of an example during normal soldering of the present disclosure.

FIG. 4 is a schematic diagram of a detection circuit of an ESD protective device employing a voice operated device of an example of the present disclosure.

FIG. 5 is a schematic diagram of a detection system of an ESD protective device employing a voice operated device of an example during inverse soldering of the present disclosure; and

FIG. 6 is a schematic diagram of a detection system of an ESD protective device employing an indicator light of an example of the present disclosure.

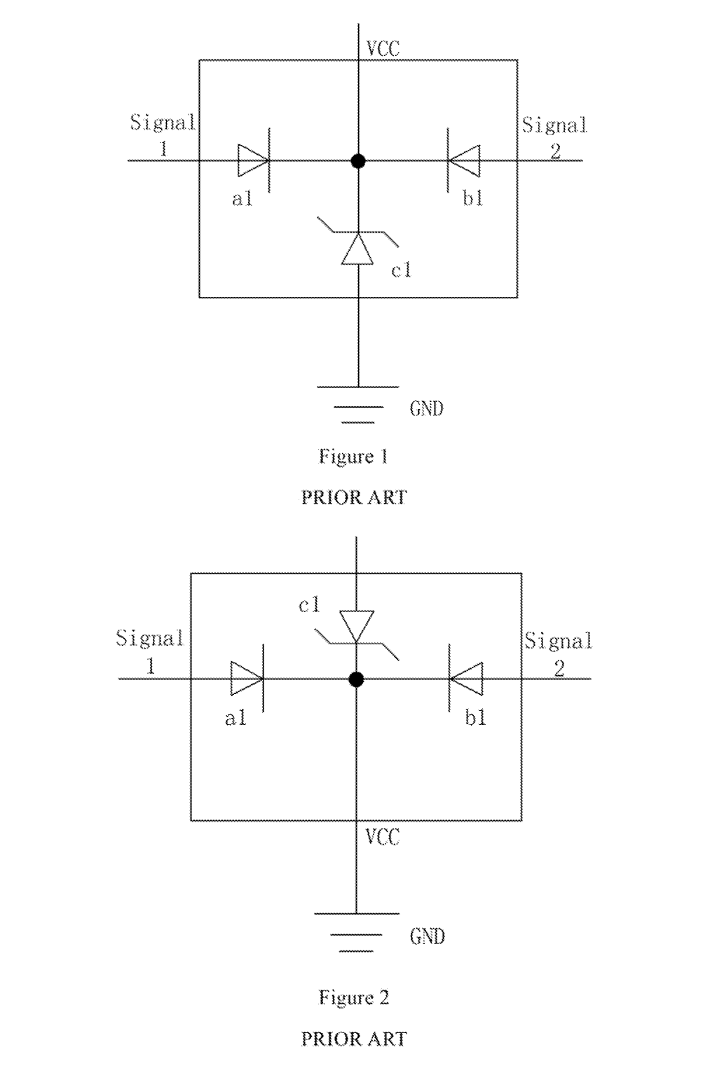

Legends: 10. operation amplifier; 20. voice operated device; 30. reference voltage; 40 indicator light.

### DETAILED DESCRIPTION

A detection circuit used for detecting an electrostatic discharge (ESD) protective device that is inversely soldered, the ESD protective device comprises a first diode, a second diode, and a third diode. Cathodes of the first diode, the second diode and the third diode are mutually connected, and an anode of the third diode is coupled to a ground terminal of the circuit by a divider resistor. The detection circuit comprises a comparator. The comparator is configured with a first input end connected to a reference voltage, and a second input end coupled to the anode of the third diode. The comparator comprises an output end. The output end of the comparator is coupled to a warning device.

In the present disclosure, because one input end of the comparator is coupled to the anode of the third diode of the ESD protective device, and is grounded by a resistor which is in series connection with the third diode, when the ESD protective device is normally soldered or inversely soldered, voltage difference at two ends of the resistor are different. Thus, the comparator can detect the voltage change of the two ends of the resistor, and output signal(s) to drive the warning device to output a corresponding action, thereby detection circuit automatically detects whether the ESD protective device is inversely soldered or not.

The present disclosure will further be described in detail in accordance with the figures and the preferable examples.

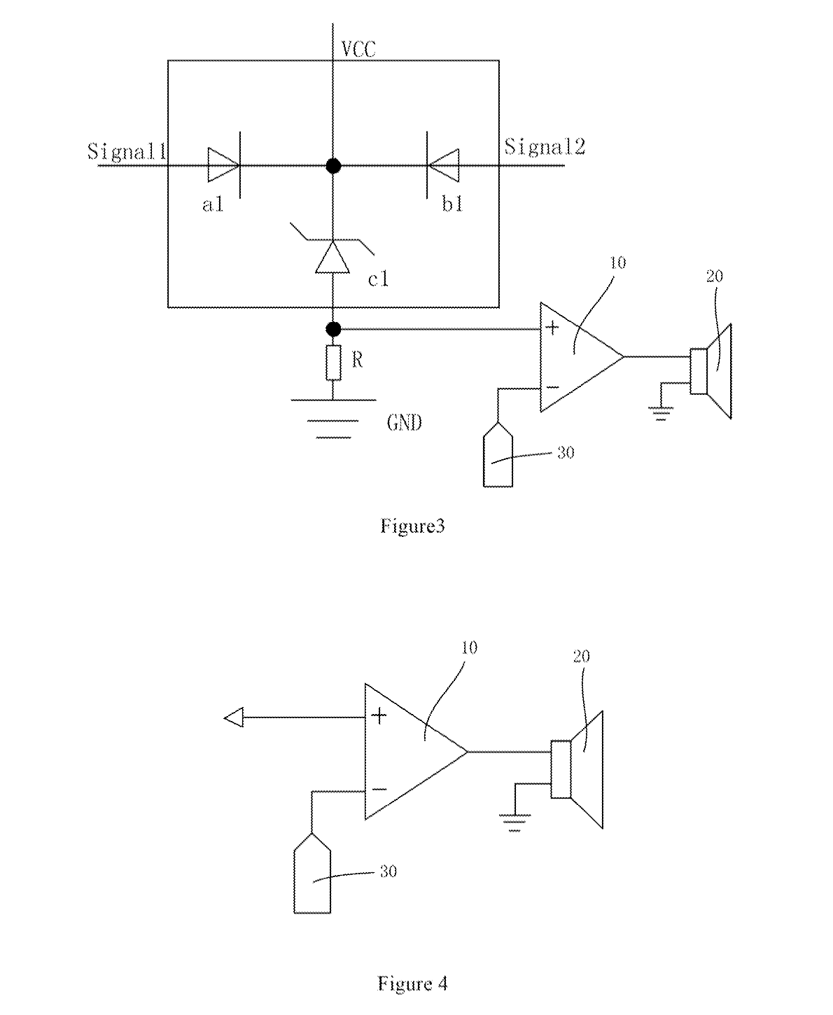

A detection circuit used for detecting the ESD protective device that is inversely soldered is disclosed in the example. As shown in FIG. 3, the ESD protective device comprises a first diode a1, a second diode b1 and a third diode c1. Cathodes of the first diode a1, the second diode b1 and the third diode c1 are mutually connected, and an anode of the third diode is coupled to the ground terminal of the circuit by the divider resistor R. In the example, as shown in FIG. 4, the detection circuit comprises an operation amplifier 10. A positive input end of the operation amplifier 10 is coupled to a non-ground terminal of the divider resistor R, and a negative input end of the operation amplifier 10 is connected to a reference voltage 30. An output end of the operation amplifier 10 is connected with an anode of a voice operated device 20 (such as a loudspeaker), and a cathode of the voice operated device 20 is grounded.

As shown in FIG. 3, when the ESD protective device is not inversely soldered, signal(s) passes the first diode al but is unable to pass the third diode c1. At this moment, there is no substantial voltage at the positive input end of the operation amplifier. Therefore, the voltage of the positive input end of the operation amplifier 10 is less than the reference voltage 30 of the negative input end, the operation amplifier 10 outputs a low electrical level, and the voice operated device 20 does not work.

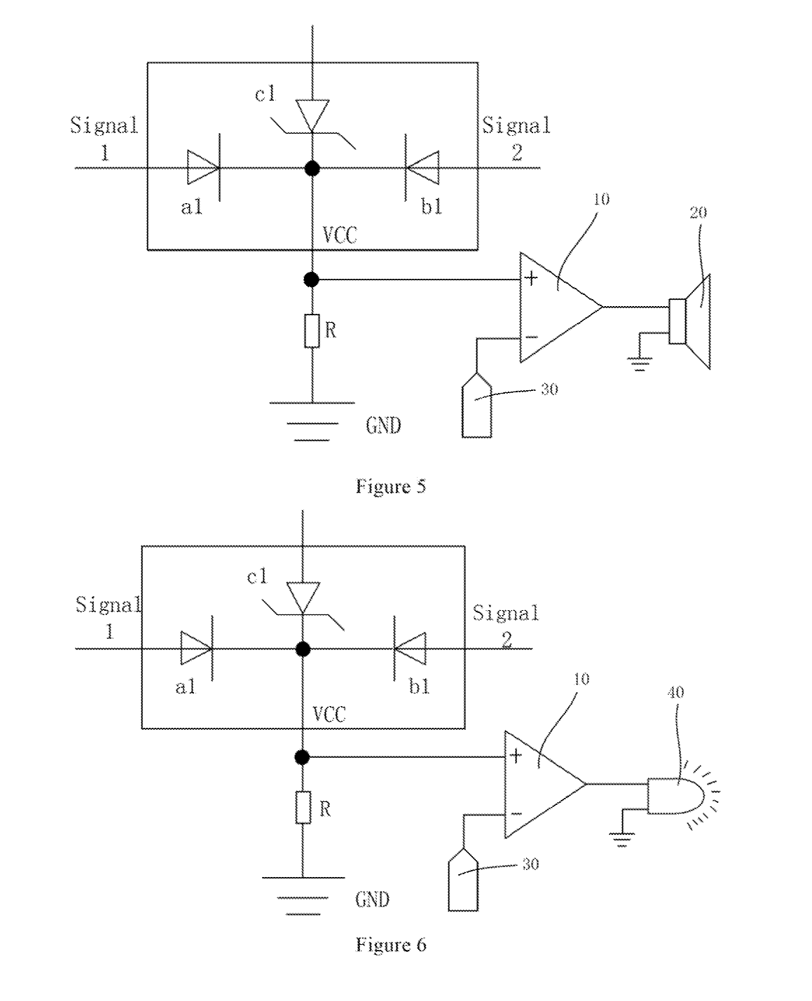

As shown in FIG. 5, when the ESD protective device is inversely soldered, signal(s) passes the second diode b1, and Vcc flows to the positive input end of the operation amplifier 10, so that the voltage of the positive input end of the operation amplifier 10 is higher than the reference voltage 30 of the negative input end, the operation amplifier 10 outputs a high electrical level, and the voice operated device 20 works and makes a sound. Thus, the inverse soldering of the ESD protective device can be detected in time.

Optionally, two input pins of the operation amplifier 10 can be inversely connected, namely the positive input end of the operation amplifier 10 is connected with the reference voltage 30, and the negative input end of the operation amplifier 10 is coupled to the non-ground terminal of the divider resistor R. Output logic is also contrary at this in moment. The voice operated device 20 works during normal soldering and makes a sound, and does not make a sound during inverse soldering.

In addition, the warning device of the present disclosure is not limited to the voice operated device 20. Light control warning devices, electrical control warning devices and the like can also be used. As show in FIG. 6, the warning function can also be achieved by replacing the loudspeaker of the voice operated device 20 with the indicator light 40.

The present disclosure further discloses a method used for detecting the ESD protective device for soldering inversion, comprising the following steps:

A: connecting the output end of the operation amplifier 10 of the detection circuit to the loudspeaker of the voice operated device 20; and

B: connecting the negative input end of the operation amplifier 10 of the detection circuit to the reference voltage 30, and connecting the positive input end of the operation amplifier 10 to the anode of the third diode of the ESD protective device.

As shown in FIG. 3, when the ESD protective device is not inversely soldered, signal(s) passes the first diode al but is unable to pass the third diode c1. At this moment, there is no substantial voltage at the positive input end of the operation amplifier. Therefore, the voltage of the positive input end of the operation amplifier 10 is less than the reference voltage 30 of the negative input end, the operation amplifier 10 outputs a low electrical level, and the voice operated device 20 does not work.

As shown in FIG. 5, when the ESD protective device is inversely soldered, signal(s) passes the second diode b1, Vcc flows to the positive input end of the operation amplifier 10, so that the voltage of the positive input end of the operation amplifier 10 is higher than the reference voltage 30 of the negative input end, the operation amplifier 10 outputs a high electrical level, and the voice operated device 20 works and makes a sound. Thus, the inverse soldering of the ESD protective device can be detected in time.

Optionally, the two input pins of the operation amplifier 10 can be inversely connected, namely the positive input end of the operation amplifier 10 is connected with the reference voltage 30, and the negative input end of the operation amplifier 10 is coupled to the non-ground terminal of the divider resistor The output logic is also contrary at this moment. The voice operated device 20 works during normal soldering and makes a sound, and does not make a sound during inverse soldering.

In addition, the warning device of the present disclosure is not limited to use the voice operated device 20. Light control warning devices, electric control warning devices and the like can also be used. As show in FIG. 6, the warning function can also be achieved by replacing the loudspeaker of the voice operated device 20 with the indicator light 40.

Another type of voltage comparator can also be used as the comparator of the present disclosure, such as converter. The converter is connected in the ESD circuit in series, and the current signal is converted into a voltage signal, to drive the warning device to take corresponding action.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

We claim:

1. A detection circuit used for detecting an electrostatic discharge (ESD) protective device that is inversely soldered, the ESD protective device comprising a first diode, a second diode, and a third diode; cathodes of the first diode, the second diode and the third diode are mutually connected, and an anode of the third diode is coupled to a ground terminal of the circuit by a divider resistor;
wherein the detection circuit comprises a comparator, the comparator is configured with a first input end connected to a reference voltage and a second input end coupled to the anode of the third diode, and an output end of the comparator is coupled to a warning device;
wherein the warning device is a voice operated device, an anode of the voice operated device is coupled to the output end of the comparator, and a cathode of the voice operated device is grounded; and
wherein the comparator comprises an operation amplifier, a positive input end of the operation amplifier is coupled to a non-ground terminal of the divider resistor, and a negative input end of the operation amplifier is connected to a reference voltage.

2. A detection circuit used for detecting an electrostatic discharge (ESD) protective device that is inversely soldered, the ESD protective device comprising a first diode, a second diode, and a third diode; the cathodes of the first diode, the second diode and the third diode are mutually connected, and an anode of the third diode is coupled to a ground terminal of the circuit by a divider resistor;
wherein the detection circuit comprises a comparator; the comparator is configured with a first input end connected to the reference voltage and a second input end coupled to the anode of the third diode, and an output end of the comparator is coupled to a warning device.

3. The detection circuit used for detecting the ESD protective device that is inversely soldered of claim 2, wherein the warning device is a voice operated device; an anode of the voice operated device is coupled to the output end of the comparator, and a cathode of the voice operated device is grounded.

4. The detection circuit used for detecting the ESD protective device that is inversely soldered of claim 2, wherein the warning device comprises an indicator light; an anode of the indicator light is coupled to the output end of the comparator, and a cathode of the indicator light is grounded.

5. The detection circuit used for detecting the ESD protective device that is inversely soldered of claim 2, wherein the comparator comprises an operation amplifier; a positive input end of the operation amplifier is coupled to a non-ground terminal of the divider resistor, and a negative input end of the operation amplifier is connected to a reference voltage.

6. The detection circuit used for detecting the ESD protective device that is inversely soldered of claim 2, wherein the comparator comprises an operation amplifier; a positive input end of the operation amplifier is connected to a reference voltage, and a negative input end of the operation amplifier is coupled to a non-ground terminal of the divider resistor.

7. A method for detecting an electrostatic discharge (ESD) protective device that is inversely soldered, comprising:
A: coupling an output end of a comparator of a detection circuit to a warning device; and
B: connecting a first input end of the comparator of the detection circuit to a reference voltage, and connecting a second input end of the comparator of the detection circuit to an anode of the third diode of the ESD protective device.

8. The method used for detecting the ESD protective device that is inversely soldered of claim 7, wherein in the step A, the warning device is a voice operated device; an anode of the voice operated device is coupled to the output end of the comparator, and a cathode of the voice operated device is grounded.

9. The method used for detecting the ESD protective device that is inversely soldered of claim 7, wherein in the step A, the warning device comprises an indicator light; an anode of the indicator light is coupled to the output end of the comparator, and a cathode of the indicator light is grounded.

10. The method used for detecting the ESD protective device that is inversely soldered claim 7, wherein in the step B, the comparator of the detection circuit comprises an operation amplifier; a positive input end of the operation amplifier is coupled to a non-ground terminal of the divider resistor, and a negative input end of the operation amplifier is connected to a reference voltage.

11. The method used for detecting the ESD protective device that is inversely soldered of claim 7, wherein in the step B, the comparator of the detection circuit comprises an operation amplifier; a positive input end of the operation amplifier is connected to a reference voltage, and a negative input end of the operation amplifier is coupled to a non-ground terminal of the divider resistor.
